(19) United States
(12) Patent Application Publication
(10) Pub. No.: US 2026/0169372 A1
(43) Pub. Date: Jun. 18, 2026

(54) METHOD FOR OPC AND METHOD OF MANUFACTURING SEMICONDUCTOR DEVICE USING THE SAME

(71) Applicant: SAMSUNG ELECTRONICS CO., LTD., Suwon-si (KR)

(72) Inventors: Yangwoo HEO, Suwon-si (KR); Sangwook KIM, Suwon-si (KR); Jihyeon WOO, Suwon-si (KR)

(73) Assignee: SAMSUNG ELECTRONICS CO., LTD., Suwon-si (KR)

(21) Appl. No.: 19/225,065

(22) Filed: Jun. 2, 2025

(30) Foreign Application Priority Data
Dec. 18, 2024 (KR) 10-2024-0190195

(51) Int. Cl. G03F 1/36; G06T 5/80; G06T 7/13

(52) U.S. Cl. CPC G03F 1/36; G06T 5/80; G06T 7/13; G06T 2207/30148

(57) ABSTRACT

A method of manufacturing a semiconductor device includes: performing optical proximity correction on a layout to generate a corrected layout; and forming a photoresist pattern on a substrate using a photomask formed using the corrected layout. The performing of the optical proximity correction includes: generating a first mask image for a mask pattern, the first mask image including a main pattern and an auxiliary pattern in the layout; and performing a coupling filter process on the mask pattern in the layout to correct the first mask image. The performing of the coupling filter process includes extracting coupling edge pairs of the mask pattern and applying a coupling edge filter to at least one of the extracted coupling edge pairs. The performing of the coupling filter process is omitted for the auxiliary pattern.

### CROSS-REFERENCE TO RELATED APPLICATION

This application claims priority under 35 U.S.C. § 119 to Korean Patent Application No. 10-2024-0190195 filed on December 18, 2024, in the Korean Intellectual Property Office, the disclosure of which is incorporated by reference in its entirety.

### BACKGROUND

The present disclosure relates to a method of manufacturing a semiconductor device, and more specifically, to a method of manufacturing a semiconductor device using an optical proximity correction (OPC) method.

Due to their small-sized, multifunctional and/or low-cost characteristics, semiconductor devices are widely used in the electronics industry. Examples of semiconductor devices include a memory device for storing logic data, a logic device for processing the logic data and a hybrid device including both memory and logic elements. As electronics industry develops, demands on the characteristics of semiconductor devices are increasing. For example, the demands on high reliability, high speed, and/or multi-functionality of semiconductor devices are increasing.

### SUMMARY

One or more embodiments provide a method for optical proximity correction (OPC) to reduce an OPC processing time.

One or more embodiments also provide a method of manufacturing a semiconductor device with improved productivity.

Problems to be solved are not limited those mentioned above, and other problems not mentioned may be clearly understood by those skilled in the art from the description below.

According to an aspect of an embodiment, a method of manufacturing a semiconductor device includes: performing optical proximity correction on a layout to generate a corrected layout; and forming a photoresist pattern on a substrate using a photomask formed using the corrected layout. The performing of the optical proximity correction includes: generating a first mask image for a mask pattern, the first mask image including a main pattern and an auxiliary pattern in the layout; and performing a coupling filter process on the mask pattern in the layout to correct the first mask image. The performing of the coupling filter process includes extracting coupling edge pairs of the mask pattern and applying a coupling edge filter to at least one of the extracted coupling edge pairs. The performing of the coupling filter process is omitted for the auxiliary pattern.

According to another aspect of an embodiment, a method of manufacturing a semiconductor device includes: performing optical proximity correction on a layout to generate a corrected layout; and forming a photoresist pattern on a substrate using a photomask formed using the corrected layout. The optical proximity correction includes: generating a first mask image for a main pattern and an auxiliary pattern in the layout; extracting edges of the main pattern; performing a first correction of applying an edge filter to the edges of the main pattern to correct the first mask image; and performing a second correction of extracting coupling edge pairs from the edges of the main pattern and applying a coupling edge filter to at least one of the extracted coupling edge pairs to correct the first mask image. The extracting of coupling edge pairs from edges of the auxiliary pattern is omitted.

According to another aspect of an embodiment, a method of manufacturing a semiconductor device includes: generating a first mask image for a main pattern and an auxiliary pattern in a layout; extracting edges of the main pattern; performing a first correction of correcting the first mask image by applying an edge filter to the edges of the main pattern; performing a second correction of correcting the first mask image by extracting coupling edge pairs from the edges of the main pattern and applying a coupling edge filter to the extracted coupling edge pairs to generate a final mask image; obtaining a photomask with a corrected layout including the main pattern and the auxiliary pattern having the final mask image; forming an etching target layer and a photoresist layer on a substrate; exposing and developing the photoresist layer with the photomask to form photoresist patterns; and patterning the etching target layer using the photoresist patterns. The extracting of coupling edge pairs from edges of the auxiliary pattern is omitted.

According to another aspect of an embodiment, a device includes: one or more memories storing instructions; and one or more processors configured to execute the instructions to control the device to: perform optical proximity correction on a layout to generate a corrected layout; and form a photoresist pattern on a substrate using a photomask formed using the corrected layout. The one or more processors are further configured to execute the instructions to control the device to perform the optical proximity correction by: generating a first mask image for a mask pattern, the first mask image including a main pattern and an auxiliary pattern in the layout; and performing a coupling filter process on the mask pattern in the layout to correct the first mask image. The performing of the coupling filter process includes extracting coupling edge pairs of the mask pattern and applying a coupling edge filter to at least one of the extracted coupling edge pairs. The one or more processors are further configured to execute the instructions to control the device to omit performing of the coupling filter process is omitted for the auxiliary pattern.

The one or more processors may be further configured to execute the instructions to control the device to generate first mask image for the mask pattern by generating a mask image by a thin mask approximation of the mask pattern.

The one or more processors may be further configured to execute the instructions to control the device to perform the coupling filter process by extracting coupling edge pairs of the main pattern and applying the coupling edge filter to the extracted coupling edge pairs of the main pattern, and omitting the extracting of coupling edge pairs of the auxiliary pattern.

The one or more processors may be further configured to execute the instructions to control the device to omit the applying of the coupling edge filter to the coupling edge pairs of the auxiliary pattern.

The one or more processors may be further configured to execute the instructions to control the device to generate a second mask image for the auxiliary pattern through a first additional correction and a second additional correction for the first mask image of the auxiliary pattern.

The one or more processors may be further configured to execute the instructions to control the device to generate a final mask image based on a difference between the second mask image and the corrected first mask image of the main pattern, and a difference between the second mask image the auxiliary pattern obtained by the performing of the coupling filter process.

The one or more processors may be further configured to execute the instructions to control the device to perform the first additional correction by blurring the first mask image of the auxiliary pattern, and the second additional correction may include applying a coefficient value to the blurred first mask image.

The one or more processors may be further configured to execute the instructions to control the device to perform an edge filter process on the mask pattern in the layout to correct the first mask image, and the edge filter process may include extracting edges of the main pattern, and applying an edge filter to the extracted edges to correct the first mask image.

The auxiliary pattern may include a plurality of auxiliary patterns adjacent to the main pattern, and the plurality of auxiliary patterns may include sub-resolution assist features (SRAF).

The plurality of auxiliary patterns may include at least one pattern having an amorphous shape.

### BRIEF DESCRIPTION OF DRAWINGS

The above and other aspects, features and advantages of embodiments will be more apparent from the following description, taken in conjunction with the accompanying drawings, in which

FIG. 1 is a block diagram illustrating a computer system for performing semiconductor design according to embodiments.

FIG. 2 is a flowchart illustrating a method for designing and manufacturing a semiconductor device according to embodiments.

FIG. 3 is a conceptual diagram illustrating a photolithography system using a photomask manufactured according to embodiments.

FIG. 4 is a flowchart schematically illustrating certain processes of optical proximity correction according to embodiments.

FIGS. 5 and 6 are layout plan views for explaining optical proximity correction, respectively.

FIG. 7 is a diagram illustrating a thin mask image according to thin mask approximation of a thin mask.

FIG. 8 is a diagram illustrating an actual mask image through simulation of an actual mask.

FIG. 9 is a layout plan view for explaining optical proximity correction.

FIG. 10 is a diagram illustrating a difference mask image obtained by subtracting the thin mask image of FIG. 7 from the actual mask image of FIG. 8.

FIGS. 11A, 11B, 12, 13A and 13B are layout plan views for explaining optical proximity correction, respectively.

FIG. 14 is a flowchart schematically illustrating certain processes of optical proximity correction according to embodiments.

FIG. 15 is a layout plan view for explaining optical proximity correction.

FIGS. 16A, 16B, 16C, 16D and 17 are graphs schematically illustrating certain processes of optical proximity correction according to embodiments, respectively.

FIG. 18 is a plan view illustrating a photomask according to embodiments.

FIG. 19 is a conceptual diagram illustrating forming photoresist patterns on a substrate using the photomask of FIG. 18.

FIGS. 20 to 27 are drawings illustrating a method of manufacturing a semiconductor device according to some embodiments.

### DETAILED DESCRIPTION

Hereinafter, embodiments will be described with reference to the attached drawings. Each embodiment provided in the following description is not excluded from being associated with one or more features of another example or another embodiment also provided herein or not provided herein but consistent with the present disclosure. As used herein, the term “and/or” includes any and all combinations of one or more of the associated listed items. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Unless indicated otherwise, terms “higher” and “lower” indicate vertical alignment in relation to the drawings. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain operation of manufacturing an apparatus or structure is described later than another operation, the operation may be performed later than the other operation unless the other operation is described as being performed after the operation.

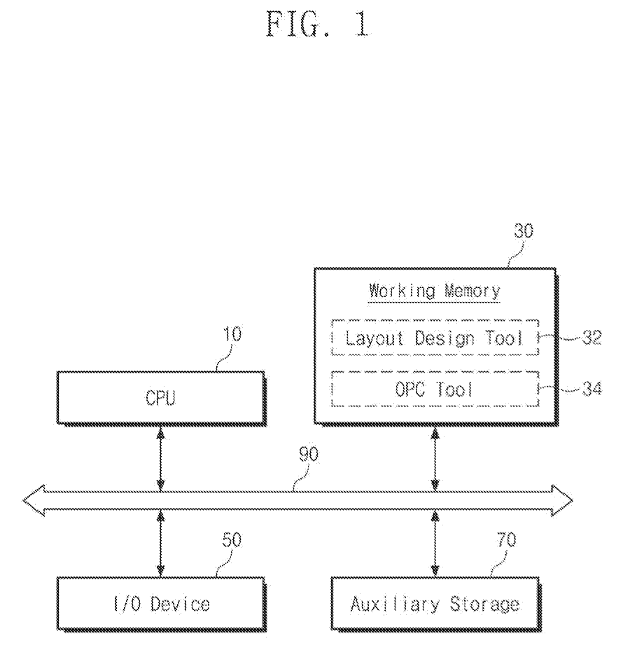

FIG. 1 is a block diagram illustrating a computer system for performing semiconductor design according to embodiments.

Referring to FIG. 1, a computer system may include a central processing unit (CPU) 10, a working memory 30, an input/output device 50, and an auxiliary storage 70. The computer system may be provided as a dedicated device for an layout design. The computer system may be equipped with various design and verification simulation programs.

The CPU 10 may execute software (application programs, operating systems, device drivers) to be executed in the computer system. The CPU 10 may execute an operating system operating system (OS) loaded into the working memory 30. The CPU 10 may execute various application programs to be driven based on the operating system OS. For example, the CPU 10 may execute a layout design tool 32 and/or an optical proximity correction (OPC) tool 34 loaded into the working memory 30. In some example embodiments, the CPU 10 may also execute other tools such as but not limited to a dummy fill tool and/or layout-versus-schematic (LVS) tool and/or a design-rule checking (DRC) tool.

An OS and/or application programs may be loaded into the working memory 30. When the computer system is booted, an OS image stored in an auxiliary storage 70 may be loaded into the working memory 30 based on the boot sequence. The OS may support various input/output operations of the computer system. The application programs may be loaded into the working memory 30 for selection by a user or for providing basic services. The layout design tool 32 and/or the OPC tool 34 may be loaded into the working memory 30 from the auxiliary storage 70. As used herein, the term “user” may refer to one or more operators and/or a technicians. Alternatively or additionally, the term “user” may refer to an artificial intelligence (AI) model such as by a large language model (LLM).

The layout design tool 32 may be equipped with a bias function that is capable of changing the shape and location of certain layout patterns differently from those defined by the design rules. In addition, the layout design tool 32 may perform design rule check (DRC) under changed bias data conditions. The OPC tool 34 may perform OPC on the layout data output from the layout design tool 32. The working memory 30 may be a volatile memory such as static random access memory (SRAM) or dynamic random access memory (DRAM), or a nonvolatile memory such as PRAM, MRAM, ReRAM, FRAM, NOR flash memory.

The input/output device 50 controls user input and output from user interface devices. For example, the input/output device 50 may be equipped with a keyboard or a monitor to receive information from a designer. The designer may be or may include an operator; alternatively or additionally, the designer may be or may include an AI engine. Using the input/output device 50, the designer may receive information about semiconductor regions or data paths that require adjusted operating characteristics. A processing process and processing results of the OPC tool 34 may be displayed through the input/output device 50.

The auxiliary storage 70 is provided as a storage medium of the computer system. The auxiliary storage 70 may store application programs, operating system images, and various data. The auxiliary storage 70 may be provided as a memory card (for example, a MultiMediaCard (MMC), embedded MultiMediaCard (eMMC), Secure Digital (SD), MicroSD, etc.) or a hard disk drive (HDD). The auxiliary storage 70 may include a NAND-type Flash memory having a large storage capacity. Alternatively, the auxiliary storage 70 may include a next-generation nonvolatile memory such as PRAM, MRAM, ReRAM, FRAM, or NOR flash memory.

A system interconnector 90 may be a system bus for providing a network in the computer system. The system interconnector 90 may be or may include a wired bus and/or a wireless bus; example embodiments are not limited thereto. Through the system interconnector 90, the CPU 10, the working memory 30, the input/output device 50, and the auxiliary storage 70 are electrically connected and may exchange data with each other. However, a configuration of the system interconnector 90 is not limited to the above-described description, and may further include arbitration components for efficient management.

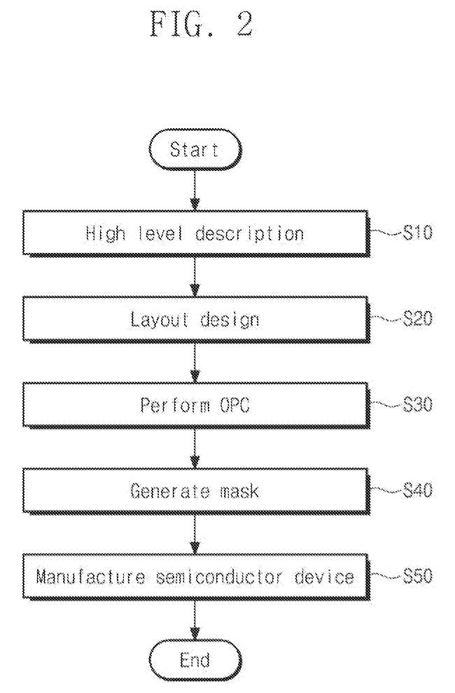

FIG. 2 is a flowchart illustrating a method for designing and manufacturing a semiconductor device according to embodiments.

Referring to FIG. 2, a high-level design of a semiconductor integrated circuit may be performed using the computer system described with reference to FIG. 1 in S10. The high-level design may indicate a design target integrated circuit in a high-level language of a computer language. For example, a high-level language such as the C language may be used. Alternatively or additionally, the higher level language may include one or more of Verilog or VHDL. Circuits designed by the high-level design may be expressed more in detail by register transfer level (RTL) coding or simulation. Furthermore, a code generated by the register transfer level coding may be converted into a netlist and synthesized into an entire semiconductor device. The synthesized schematic circuit may be verified by a simulation tool, and an adjustment process may be performed in response to the verified result.

A layout design for implementing a logically completed semiconductor integrated circuit on a silicon substrate may be performed in S20, for example by preparing one or more layouts corresponding to one or more features to be patterned and/or etched and/or implanted on a substrate. For example, the layout design may be performed in response to a schematic circuit synthesized in a high-level design or a corresponding netlist. The layout design may include a routing procedure for placing and connecting various standard cells provided in a cell library according to a prescribed design rule.

The cell library for the layout design may also include information on the operation, speed, and power consumption of the standard cell. A cell library for expressing a certain gate level circuit as a layout is defined in most layout design tools. The layout may be a procedure for defining a shape or size of a pattern for configuring a transistor and metal wirings to be actually formed on a silicon substrate. For example, to actually form an inverter circuit on a silicon substrate, layout patterns such as PMOS, NMOS, N-WELL, gate electrodes, and metal wirings to be arranged thereon may be appropriately arranged. To this end, first, an appropriate one may be searched and selected from inverters already defined in the cell library.

In addition, routing may be performed on the selected and placed standard cells. In detail, routing with upper wirings may be performed on the selected and placed standard cells. Through the routing procedure, the standard cells may be connected to each other in accordance with the design. Most of these series of processes may be performed automatically or manually by the layout design tool. Furthermore, the placement the standard cells and routing of may be performed automatically using a separate Place & Routing tool.

After routing, the layout may be verified to see when there are any portions that violate the design rules. Verification items may include design rule check (DRC) that verifies whether the layout is properly in accordance with the design rules, electronical rule check (ERC) that verifies whether the layout is properly in accordance with the design rules, and layout vs schematic (LVS) that verifies whether the layout matches the gate-level netlist.

An OPC procedure may be performed in S30. Using a photolithography process, layout patterns obtained through layout design may be implemented on a silicon substrate. In this case, optical proximity correction may be a technology for correcting distortion phenomena that may occur in the photolithography process. That is, distortion phenomena such as refraction or process effects that occur due to the characteristics of light during exposure using a laid-out pattern may be corrected through optical proximity correction. While performing optical proximity correction, a shape and position of patterns in the designed layout may be changed (biased). A more specific description of optical proximity correction will be described in detail with reference to FIGS. 4 to 17.

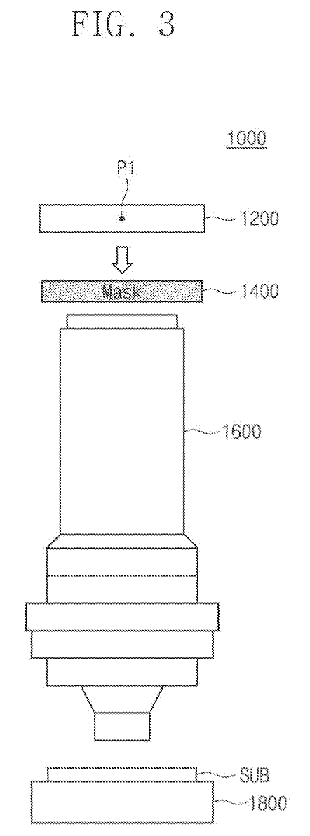

FIG. 3 is a conceptual diagram illustrating a photolithography system using a photomask manufactured according to embodiments.

Referring to FIG. 3, a photolithography system 1000 may include a light source 1200, a photomask 1400, a reduction projection device 1600, and a substrate stage 1800. However, the photolithography system 1000 may further include components not shown in FIG. 3. For example, the photolithography system 1000 may further include a sensor used to measure a height and inclination of a surface of a substrate SUB.

The light source 1200 may emit light. The light emitted from the light source 1200 may be irradiated to the photomask 1400. For example, a lens may be provided between the light source 1200 and the photomask 1400 to adjust a light focus. The light source 1200 may include an ultraviolet light source (e.g., a KrF light source having a wavelength of 234 nm, an ArF light source having a wavelength of 193 nm, etc.) or an extreme ultraviolet (EUV) light source. The light source 1200 according to an embodiment may be an EUV light source. The light source 1200 may include one point light source P1, but embodiments are not limited thereto. In other embodiments, the light source 1200 may include a plurality of point light sources.

To print (to implement) a designed layout on the substrate SUB, the photomask 1400 may include image patterns. The image patterns may be formed based on the layout patterns obtained through the layout design and optical proximity correction described above. The image patterns may be defined by transparent regions and opaque regions of the photomask 1400. The transparent region may be formed by etching a metal layer (e.g., a chrome layer) on the photomask 1400. The transparent region may transmit the light emitted from the light source 1200. On the other hand, the opaque region may block the light without transmitting the light.

The reduction projection device 1600 may receive the light that has passed through the transparent region of the photomask 1400. The reduction projection device 1600 may match patterns to be printed on the substrate SUB with the image patterns of the photomask 1400. The light may be irradiated to the substrate SUB through the reduction projection device 1600. As a result, patterns corresponding to the image patterns of the photomask 1400 may be printed on the substrate SUB.

The substrate stage 1800 may support the substrate SUB. For example, the substrate SUB may include a silicon wafer. The reduction projection device 1600 may include an aperture. The aperture may be used to increase a depth of focus of ultraviolet light emitted from the light source 1200. For example, the aperture may include a dipole aperture or a quadruple aperture. The reduction projection device 1600 may further include one or more lenses to adjust the optical focus.

As the integration of semiconductor devices increases, a distance between the image patterns of the photomask 1400 may decrease. Due to the “proximity”, interference and diffraction of light may occur, and a distorted pattern may be printed on the substrate SUB. When the distorted pattern is printed on the substrate SUB, a designed circuit may operate abnormally.

To prevent the distortion of the pattern, a resolution enhancement technology may be used. Optical proximity correction (refer to S30 of FIG. 2) is an example of a resolution enhancement technology. According to optical proximity correction, degree of distortion such as interference and diffraction of light may be predicted in advance by simulation of the OPC model. Based on the predicted result, the designed layout may be changed (biased). Based on the changed layout, image patterns are formed on the photomask 1400, and thus a desired pattern may be printed on the substrate SUB.

The layout of the semiconductor device may include a plurality of layers. For example, the optical proximity correction may be performed to adjust the layout of a single layer. For example, the optical proximity correction may be performed a plurality of times to individually adjust each of the plurality of layers. That is, the optical proximity correction may be performed independently for each of the plurality of layers. The semiconductor device may be formed by sequentially implementing the plurality of layers on the substrate through a semiconductor process. For example, the semiconductor device may include a plurality of stacked metal layers (metal layers) to implement a certain circuit.

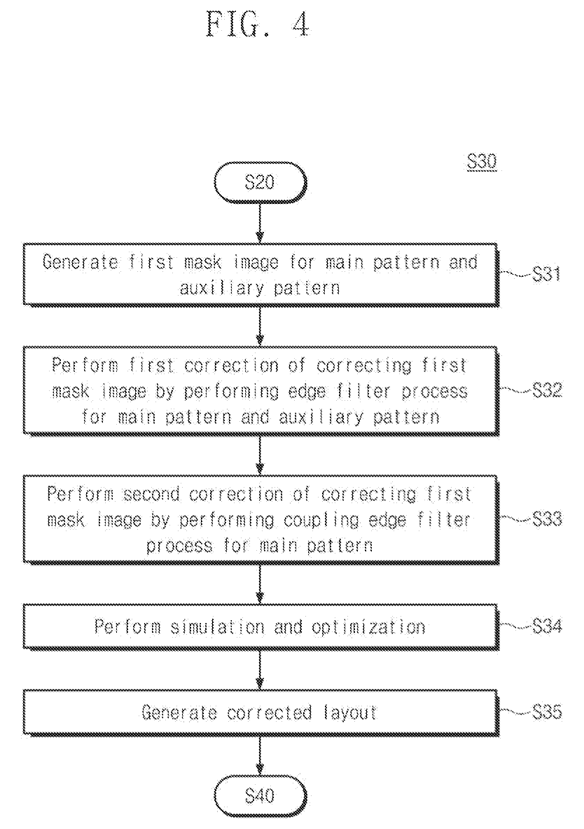

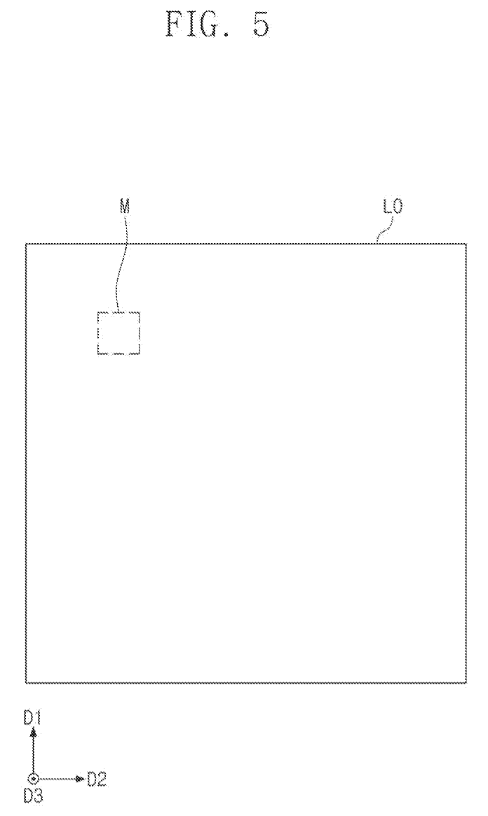

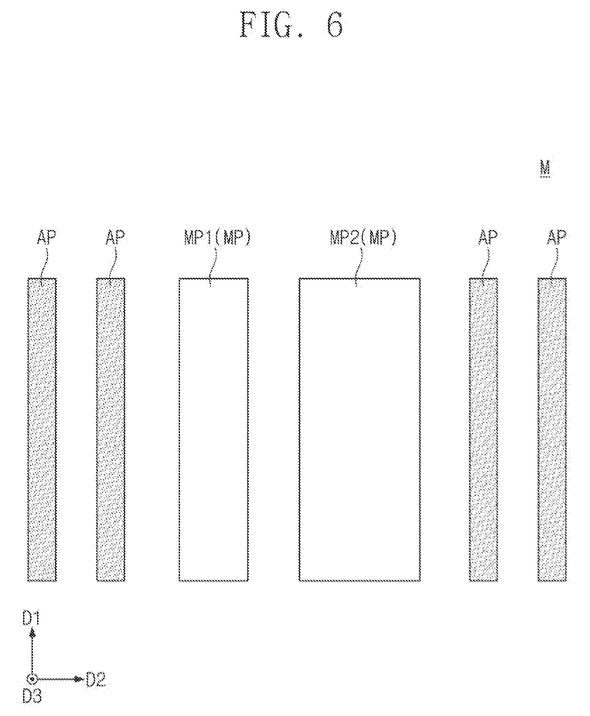

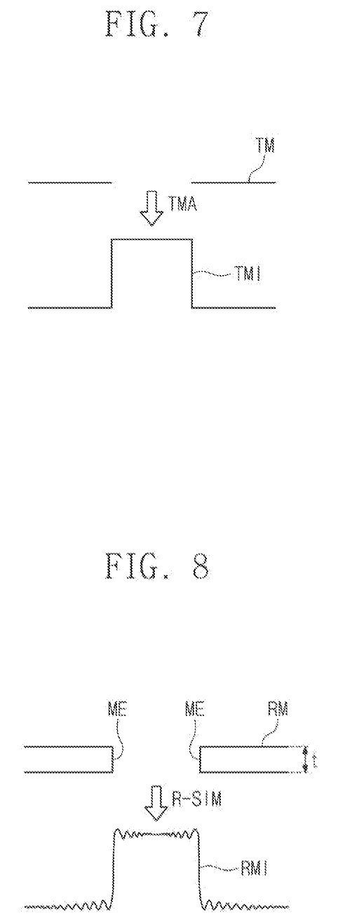

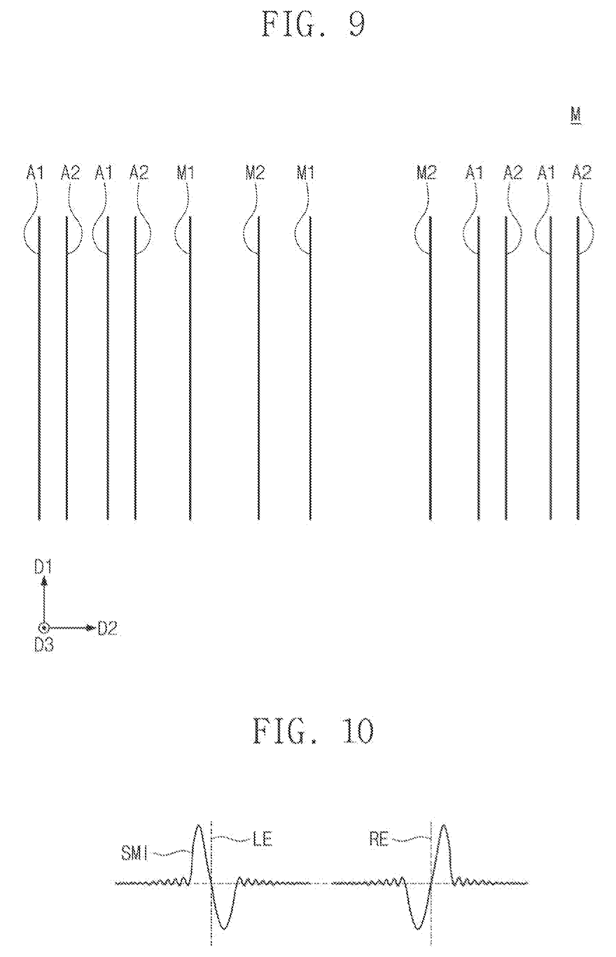

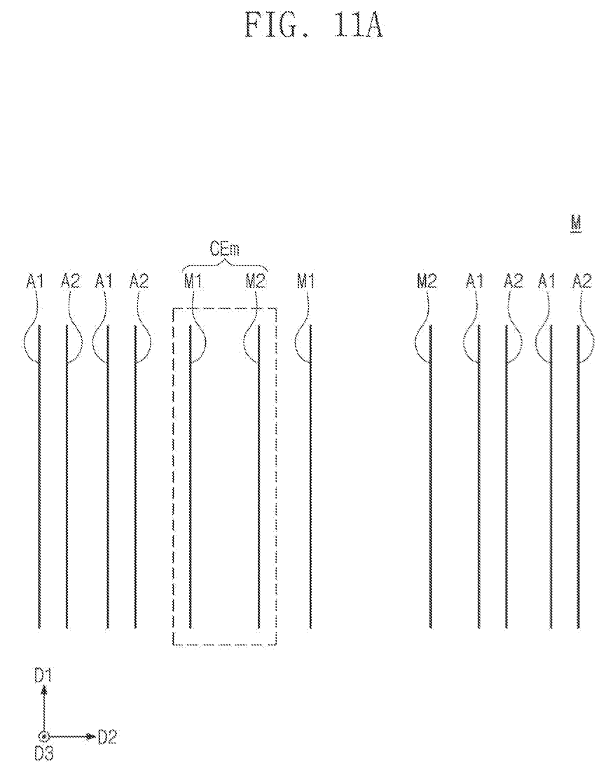

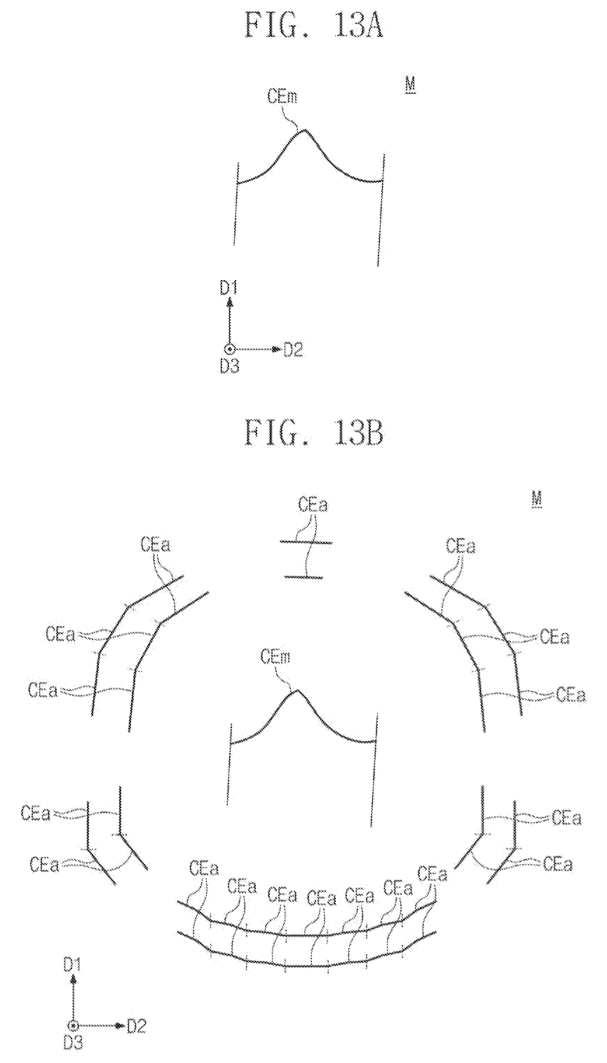

FIG. 4 is a flowchart schematically illustrating certain processes of the optical proximity correction according to embodiments. FIGS. 5, 6, 9, and 11A to 13B are layout plan views for explaining the optical proximity correction, respectively. In detail, FIGS. 6, 9, and 12 are enlarged views corresponding to ‘M’ of FIG. 5, respectively. FIG. 7 is a drawing illustrating a thin mask image according to a thin mask approximation of a thin mask. FIG. 8 is a drawing illustrating an actual mask image through simulation of an actual mask. FIG. 10 is a drawing illustrating a difference mask image obtained by subtracting the thin mask image of FIG. 7 from the actual mask image of FIG. 8. FIGS. 11A and 13A are enlarged views corresponding to ‘M’ of FIG. 5, respectively, and correspond to some embodiments. FIGS. 11B and 13B are enlarged views corresponding to ‘M’ of FIG. 5, respectively, and correspond to comparative examples.

First, referring to FIGS. 4, 5, and 6, a layout LO generated through the designing of the layout in S2 described above with reference to FIG. 2 may be provided. The layout LO may be a single-layer layout.

The layout LO may include a main pattern MP and an auxiliary pattern AP. A main pattern MP may indicate an ideal pattern to be formed on a substrate SUB (see FIG. 3) through an exposure process using a photomask, and the layout LO may indicate a layout for a pattern formed on a photomask to form the main pattern MP. Due to the characteristics of the exposure process, a shape of a photoresist pattern formed on an actual substrate SUB (see FIG. 3) may be different from a shape of the main pattern MP.

The main pattern MP may include a first main pattern MP1 and a second main pattern MP2. In FIG. 6, two main patterns MP are illustrated, but embodiments are not limited thereto. The first main pattern MP1 and the second main pattern MP2 may be disposed to extend in a first direction D1 and to be spaced apart from each other in a second direction D2, but embodiments are not limited thereto. An extension direction and a spaced-off direction of the main patterns MP may be variously changed by a person skilled in the art. In FIG. 6, the first main pattern MP1 and the second main pattern MP2 each have a bar-type shape, but embodiments are not limited thereto. The shape of the main patterns MP may be variously changed by a person skilled in the art.

An auxiliary pattern AP may indicate a small pattern provided around the main pattern MP. The auxiliary pattern AP may be smaller than a resolution of the exposure equipment, and thus may not be transferred to the photoresist pattern. A plurality of auxiliary pattern AP may be provided. The auxiliary patterns AP may be formed around the main pattern MP to optimize the shape of the main pattern MP transferred to the photoresist pattern through the exposure process. For example, the auxiliary pattern AP may include sub-resolution assist features (SRAF).

The auxiliary patterns AP may be disposed adjacent to the main patterns MP. In FIG. 6, the auxiliary patterns AP are disposed adjacent to both sides of the main patterns MP, but embodiments are not limited thereto. An arrangement of the auxiliary patterns AP may be variously changed by a person skilled in the art. In FIG. 6 each of the auxiliary patterns AP has a bar-type shape, but embodiments are not limited thereto. The shape of the auxiliary patterns AP may be variously changed by a person skilled in the art.

Performing OPC according to some embodiments may include generating a first mask image for the main pattern MP and the auxiliary pattern AP in S31, performing a first correction of correcting the first mask image by performing an edge filter process for each of the main pattern MP and the auxiliary pattern AP in S32, performing a second correction of correcting the first mask image by performing a coupling edge filter process for the main pattern MP in S33, performing a simulation and optimization in S34, and generating a corrected layout in S35.

First, referring to FIGS. 4, 6, 7, and 8, the generating of the first mask image for the main pattern MP and the auxiliary pattern AP in S31 may include generating a mask image by a thin mask approximation TMA of the main pattern MP and the auxiliary pattern AP. For example, referring to FIG. 7, a thin mask image TMI by a thin mask approximation TMA may indicate a mask image calculated assuming that a thickness of a thin mask TM is so thin and an opening portion of the thin mask TM completely passes light and a blocked portion of the thin mask TM completely blocks light. Accordingly, the generating of the first mask image in S31 for the main pattern MP and the auxiliary pattern AP may indicate generating a mask image for each of the main pattern MP and the auxiliary pattern AP assuming that the thickness of the mask formed with the layout including the main pattern MP and the auxiliary pattern AP is almost zero.

Referring to FIG. 8, an actual mask RM used for forming a pattern has a certain thickness t. Accordingly, the actual mask RM may have edges ME in an opening, and a length of the edges ME may be the certain thickness t. An actual mask image RMI formed through the actual mask RM may be calculated through simulation R-SIM such as rigorous coupled-wave analysis (RCWA) or finite difference time domain (FDTD). The actual mask image RMI by the actual mask RM having the certain thickness t may be different from the thin mask image TMI (see FIG. 7) by the thin mask TM (see FIG. 7) having almost no thickness. A difference therebetween may be due to optical effect occurring at the edges ME of the actual mask RM.

Similarly, the actual mask formed with a layout including the main pattern MP and the auxiliary pattern AP may have a certain thickness. Therefore, it may not be easy to form the desired pattern on the substrate SUB (see FIG. 3) with only the first mask image for the main pattern MP and the auxiliary pattern AP.

Next, referring to FIGS. 4, 6, 9, and 10, to reduce the difference between the actual mask image for the main pattern MP and the auxiliary pattern AP described above and the first mask image for the main pattern MP and the auxiliary pattern AP, the following operations may be performed. That is, performing a first correction of correcting the first mask image by performing an edge filter process for each of the main pattern MP and the auxiliary pattern AP may be performed in S32.

The performing of the first correction of correcting the first mask image by performing the edge filter process for each of the main pattern MP and the auxiliary pattern AP may include extracting edges for the main pattern MP and the auxiliary pattern AP and performing the first correction of correcting the first mask image by applying an edge filter to the extracted edges of the main pattern MP and the auxiliary pattern AP.

The extracting of the edges for the above-described main pattern MP and auxiliary pattern AP may include extracting edges M1 and M2 of each of the first main pattern MP1 and the second main pattern MP2 and edges A1 and A2 of each of the auxiliary patterns AP.

Applying the edge filter to the extracted edges of the main pattern MP and the auxiliary pattern AP may include applying an edge filter to the edges M1 and M2 of the above-described first main pattern MP1 and the second main pattern MP2 and edges A1 and A2 of the auxiliary patterns AP to generate a first correction mask image.

Referring to FIG. 10 as an example, the generation of the above-described first correction mask image will be described. FIG. 10 shows a form of a difference mask image SMI obtained by subtracting a thin mask image TMI of FIG. 7 from the actual mask image RMI of FIG. 8. A change in an amplitude of the difference mask image SMI may be large in portions adjacent to a left edge LE and portions adjacent to a right edge RE. In contrast, a change in an amplitude of the difference mask image SMI may become smaller as it gets farther away from the left edge LE and the right edge RE. The change in the amplitude of the difference mask image SMI in the portions adjacent to the left edge LE and the right edge RE may be due to the optical effect occurring at the edges ME of the actual mask RM described above. Each of the difference mask images SMI of the left edge LE and the right edge RE may correspond to the edge filter described above. Accordingly, the difference mask image SMI may be generated by extracting the edges of the pattern and applying the edge filter corresponding to the edges. For example, generating the first correction mask image may be the same as/similar to the generating of the difference mask image SMI of FIG. 10.

In summary, generating the first correction mask image by applying the edge filter to each of the edges M1 and M2 of the first main pattern MP1 and the second main pattern MP2 and each of the edges A1 and A2 of the auxiliary patterns AP may indicate generating the difference mask image by subtracting the first mask image (i.e., the thin mask image) for each of the first main pattern MP1, the second main pattern MP2, and the auxiliary patterns AP from the actual mask image for each of the first main pattern MP1, the second main pattern MP2 and the auxiliary patterns AP.

Thereafter, the first correction for correcting the first mask image may include adding the first correction mask image to the first mask image.

In summary, the above-described operation in S32 may include performing the first correction of extracting the edges M1 and M2 of each of the first main pattern MP1 and the second main pattern MP2 and the edges A1 and A2 of each of the auxiliary patterns AP, applying the edge filter to the extracted edges M1, M2, A1, and A2 to generate the first correction mask image, and adding the first correction mask image to the first mask image to correct the first mask image.

Even when the first mask image is corrected through the first correction, the corrected first mask image may still be different from the actual mask image. A difference may be due to the coupling effect between the edges M1 and M2 of the main pattern MP and the coupling effect between the edges A1 and A2 of the auxiliary pattern AP. When a width of each of the main pattern MP and the auxiliary pattern AP is wide and the coupling effect between the adjacent edges is minimal, a relatively accurate final mask image may be generated in S32. However, when a width of each of the main pattern MP and the auxiliary pattern AP is small and the coupling effect between the adjacent edges is large, it may not be easy to generate an accurate final mask image in S32.

Then, referring to FIGS. 4, 6, and 11A, to reduce a difference between the corrected first mask image due to the coupling effect described above and the actual mask image, a second correction of performing a coupling edge filter process on the main pattern MP to correct the first mask image may be performed in S33.

The performing of the second correction for correcting the first mask image by performing the coupling edge filter process on the main pattern MP may include performing the second correction for correcting the first mask image by extracting coupling edge pairs CEm from the edges M1 and M2 of the main pattern MP, and applying a coupling edge filter to the coupling edge pairs CEm of the main pattern MP.

The extracting of the coupling edge pairs CEm from the edges M1 and M2 of the main pattern MP may include extracting edge pairs that meet a reference condition from the edges M1 and M2 of the main patterns MP. For example, whether a distance between adjacent edges is less than or equal to a reference distance (i.e., the width of the pattern) may be a reference condition for extracting the edge pairs. For example, a reference distance may be 70 nm, and for another example, the reference distance may be 35 nm, but embodiments are not limited thereto. The reference distance may be variously changed by a person skilled in the art.

As another example, whether the coupling effect occurring between adjacent edges exceeds a reference coupling effect may be a reference condition for extracting edge pairs. The coupling effect may be described by maximum error absolute (MEA). As used herein, the MEA indicates an absolute value of the maximum value among the differences between the actual mask image (e.g., RMI of FIG. 8) and the first mask image corrected through the first correction (e.g., the mask image obtained by adding the difference mask image SMI of FIG. 10 to the thin mask image TMI of FIG. 7). As the distance between adjacent edges decreases, the coupling effect between adjacent edges may increase. Therefore, the extracting of the edge pairs based on whether the distance is less than or equal to the above-described reference distance may be substantially the same/similar to the extracting of the edge pairs based on whether the distance exceeds the above-described reference coupling effect.

According to the above-described reference conditions, the coupling edge pair CEm of the main pattern MP may be extracted. In detail, a width in the second direction D2 of the first main pattern MP1 may be less than or equal to the above-described reference distance. That is, the distance between the edges M1 and M2 adjacent in the second direction D2 of the first main pattern MP1 may be less than or equal to the reference distance. Accordingly, the edges M1 and M2 adjacent in the second direction D2 of the first main pattern MP1 may be extracted as a coupling edge pair CEm. As shown in FIG. 11A, the edges M1 and M2 adjacent in the second direction D2 of the first main pattern MP1 are extracted as a coupling edge pair CEm, but embodiments are not limited thereto. Depending on the situation, the edges adjacent in the first direction D1 of the first main pattern MP1 may also be extracted as a coupling edge pair.

In contrast, a width of the second main pattern MP2 in the second direction D2 may be greater than or equal to the above-described reference distance. That is, the distance between the edges M1 and M2 adjacent in the second direction D2 of the second main pattern MP2 may be greater than or equal to the reference distance. Accordingly, the coupling effect between the edges M1 and M2 adjacent in the second direction D2 of the second main pattern MP2 may be small. Accordingly, the edges M1 and M2 adjacent in the second direction D2 of the second main pattern MP2 may not be extracted as the coupling edge pair.

In addition, a width of each of the auxiliary patterns AP in the second direction D2 may be less than or equal to the above-described reference distance. That is, the distance between the edges A1 and A2 adjacent in the second direction D2 of each of the auxiliary patterns AP may be less than or equal to the reference distance. However, the OPC method according to some embodiments may omit the extracting of the edges A1 and A2 of the auxiliary pattern AP as the coupling edge pair. The reason for omitting the operation will be described with reference to FIG. 6 and FIG. 11B.

FIG. 11B shows, as a comparative example, the extracting of each of the coupling edge pair CEm of the main pattern MP and coupling edge pair CEa of the auxiliary pattern AP. As in FIG. 11A, as the distance between the adjacent edges M1 and M2 of the first main pattern MP1 is less than or equal to the reference distance, the adjacent edges M1 and M2 of the first main pattern MP1 may be extracted as the coupling edge pair CEm. Similarly, as the distance between the adjacent edges M1 and M2 of the second main pattern MP2 is greater than or equal to the reference distance, the adjacent edges M1 and M2 of the second main pattern MP2 may not be extracted as the coupling edge pairs.

As shown in FIG. 11B, unlike FIG. 11A, the OPC method according to the comparative example may extract the adjacent edges A1 and A2 of the auxiliary patterns AP as coupling edge pairs CEa when a distance between the adjacent edges A1 and A2 of the auxiliary patterns AP in the second direction D2 is less than or equal to the reference distance. In this case, it may take time to find the edges A1 and A2 among the adjacent edges A1 and A2 of the auxiliary patterns AP whose distance therebetween is less than or equal to the reference distance, and to extract the coupling edge pairs CEa. Therefore, a time required for the OPC method according to the comparative example may be longer than a time required for the OPC method according to some embodiments that omit the extracting of the edges A1 and A2 of the auxiliary pattern AP as a coupling edge pair. Even though FIG. 11B illustrates four auxiliary patterns AP, the number of auxiliary patterns AP may increase further depending on the number, arrangement, and shape of main patterns MP. In this case, the time required for the OPC method according to the comparative example may be further increased.

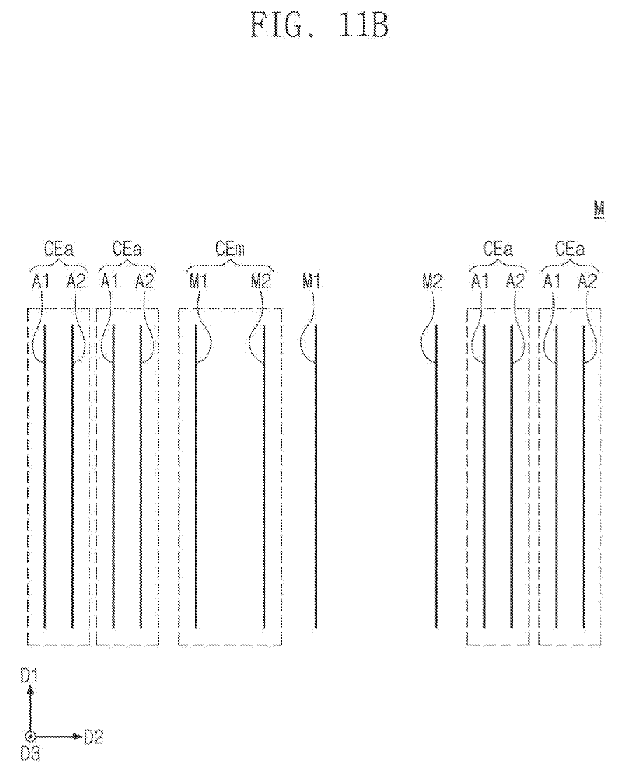

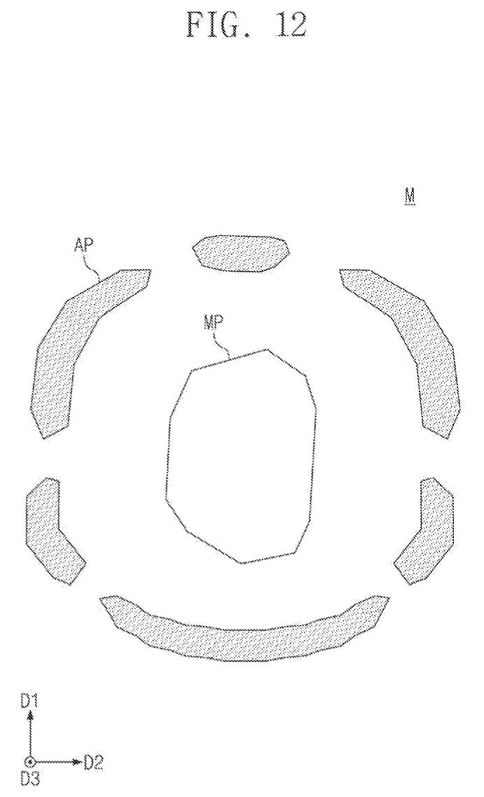

The time required for the OPC method according to the comparative example and the time required for the OPC method according to some embodiments may be more clearly different when performing OPC on a layout including amorphously shaped (i.e., free-form) patterns described with reference to FIGS. 12, 13A, and 13B.

Referring to FIGS. 12, 13A, and 13B, unlike what was described with reference to FIG. 6, each of the main pattern MP and the auxiliary pattern AP may have a an amorphous (i.e., free-form) form. For example, each of the main pattern MP and the auxiliary pattern AP may have an irregular or free-form shape that does not correspond to linear or standard curved geometries, in contrast to regular, symmetrical geometric forms such as a rectangle or a circle. Accordingly, each of the main pattern MP and the auxiliary pattern AP may have numerous edges that may be distinguished.

First, referring to FIGS. 12 and 13A, when extracting coupling edge pairs, the OPC method according to some embodiments may extract only the coupling edge pair CEm of the main pattern MP, and extraction of the coupling edge pairs of the auxiliary patterns AP may be omitted. Therefore, as illustrated in the drawings, one pair of coupling edge pairs CEm of the main pattern MP may be extracted.

In contrast, referring to FIGS. 12 and 13B, the OPC method according to the comparative example extracts coupling edge pairs CEa of auxiliary patterns AP as well as coupling edge pairs CEm of the main pattern MP when extracting coupling edge pairs. Accordingly, as illustrated in FIG. 13B, one pair of coupling edge pairs CEm of the main pattern MP and 18 coupling edge pairs CEa of the auxiliary patterns AP may be extracted.

In summary, based on FIGS. 13A and 13B, the OPC method according to the comparative example may extract 18 more coupling edge pairs CEa than the OPC method according to some embodiments. As a result, a process time of the OPC method according to the comparative example may be greater than that of the OPC method according to some embodiments. The OPC method according to the comparative is illustrated in FIG. 13B as extracting 18 pairs of coupling edge pairs CEa of the auxiliary patterns AP, but is not limited thereto. Depending on the number, arrangement, shape, of auxiliary patterns AP, the OPC method according to the comparative example may extract a greater number of coupling edge pairs.

According embodiments, when extracting coupling edge pairs to reduce the difference between the corrected first mask image and the actual mask image due to the coupling effect, the extracting of the edges A1 and A2 of the auxiliary pattern AP as the coupling edge pairs may be omitted. Accordingly, only the extracting of the edges M1 and M2 of the main pattern MP as the coupling edge pairs may be performed. As a result, a time required for the OPC method may be reduced. Accordingly, productivity of the semiconductor device manufacturing method may be improved.

Referring back to FIGS. 4, 6, and 11A, after the extracting of the coupling edge pairs CEm from the edges M1 and M2 of the above-described main pattern MP is completed, a second correction of applying a coupling edge filter to the coupling edge pairs CEm of the main pattern MP to correct the first mask image in S33 may be performed.

Applying the coupling edge filter to the coupling edge pairs CEm of the main pattern MP may include generating a second correction mask image for the main pattern MP. For example, referring back to FIGS. 7, 8, and 10, generating the second correction mask image may indicate a mask image obtained by adding the first correction mask image (i.e., the difference mask image SMI) to the first mask image (i.e., the thin mask image TMI) and subtracting the actual mask image RMI from the mask image.

The second correction for correcting the first mask image may include adding the second correction mask image to the first mask image that has undergone the first correction described above.

When performing the operation in S33, unlike the comparative example, applying of coupling edge filter to coupling edge pairs of the auxiliary pattern AP may be omitted.

According to embodiments, the extracting of the coupling edge pairs from the edges A1 and A2 of the auxiliary pattern AP may be omitted, and applying a coupling edge filter to the coupling edge pairs CEa of the auxiliary pattern AP may be omitted in the second correction of correcting the first mask image. Accordingly, only the second correction of correcting the first mask image by applying the coupling edge filter to the coupling edge pairs CEm of the main pattern MP may be performed. As a result, a time required for the OPC method may be reduced. Accordingly, productivity of the semiconductor device manufacturing method may be improved.

Thereafter, referring to FIGS. 4 and 5, the simulation and optimization work in S36 may be performed on the corrected first mask image that has undergone the first correction and the second correction. Performing the simulation may include extracting a contour for a pattern in the layout LO. As used herein, the contour may indicate an actual photoresist pattern formed on the substrate SUB (see FIG. 3) when an exposure process is performed through a photomask formed based on the layout LO. Therefore, a purpose of the OPC method may be to make the contour as similar as possible to a shape of a pattern of the layout LO.

For example, when an edge placement error (EPE) of the pattern and the contour in the layout LO is calculated and the EPE does not exceed specifications set by the user, the OPC procedure may be terminated without a separate correction for the layout LO including the corrected first mask image that has undergone the first correction and the second correction.

In contrast, as another example, when the edge placement error (EPE) of the pattern and contour in the layout LO is calculated and the EPE exceeds the specifications set by the user, an optimization for the layout LO may be performed. In this case, the simulation may be performed again for the corrected layout LO by performing the optimization. In this case, when the edge placement error (EPE) of the pattern and the contour in the corrected layout LO is calculated and the EPE does not exceed the specifications set by the user, the OPC procedure may be terminated without an additional optimization. Through this process, the generating of the corrected layout is performed in S37, and thus the OPC procedure may be terminated.

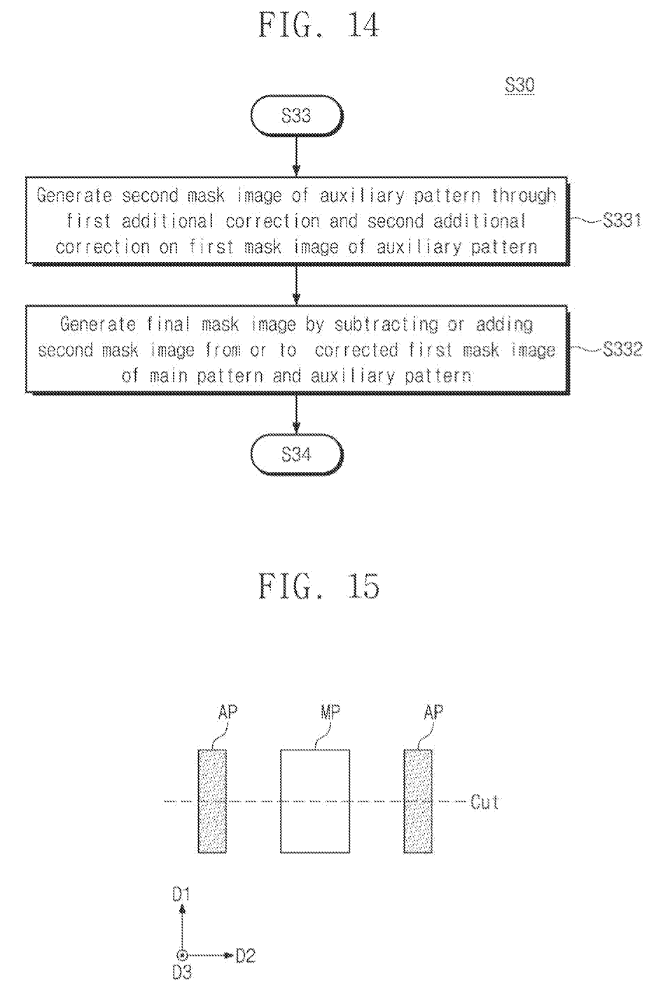

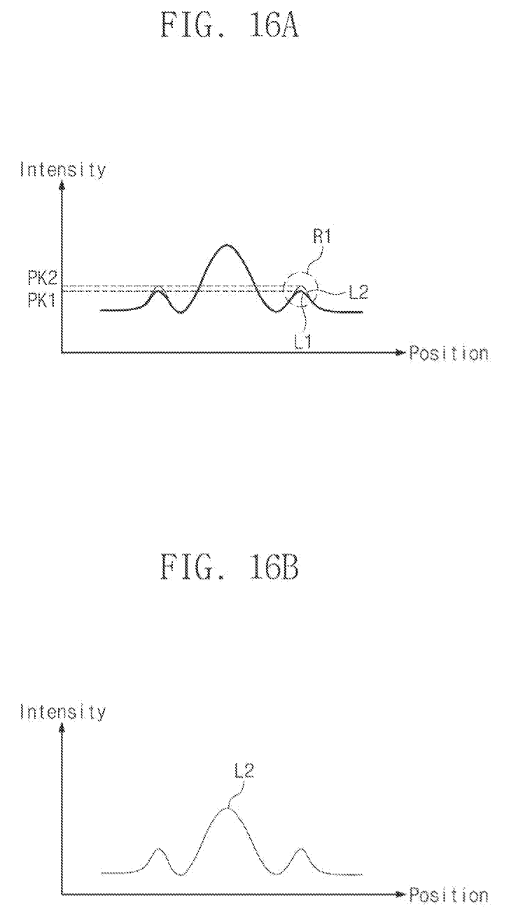

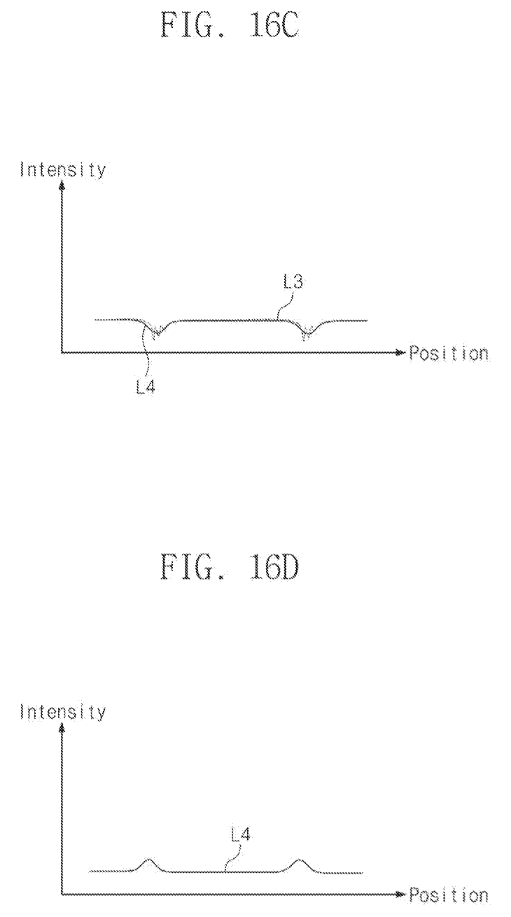

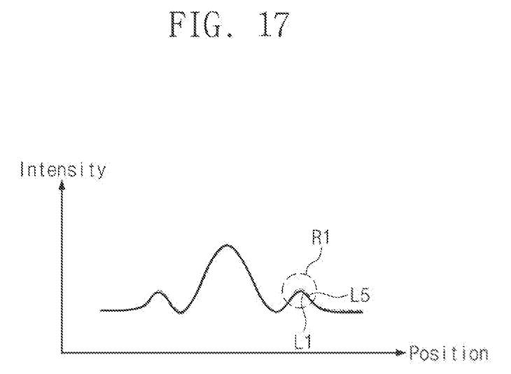

FIG. 14 is a flowchart schematically illustrating certain processes of optical proximity correction according to embodiments. FIG. 15 is a layout plan for explaining optical proximity correction, and is an enlarged view corresponding to ‘M’ of FIG. 5. FIGS. 16A to 17 are graphs schematically illustrating certain processes of optical proximity correction according to embodiments, respectively.

First, referring to FIGS. 15 and 16A, FIG. 16A is a graph illustrating an optical image for a mask image of a main pattern MP and an auxiliary pattern AP of FIG. 15. In detail, the mask image of the main pattern MP and the auxiliary pattern AP may be a first mask image that has undergone the first correction and the second correction described above. In addition, the optical image of the mask image of the main pattern MP and the auxiliary pattern AP may be an optical image of a mask image of a cross-section of each of the main pattern MP and the auxiliary pattern AP in the second direction D2 in FIG. 16A.

In FIG. 16A, an x-axis represents a position of the patterns, and a y-axis represents an intensity of the optical image. A first line L1 is an optical image for a corrected first mask image obtained by performing the OPC method according to a comparative example described with reference to FIG. 11B. A second line L2 is an optical image for a corrected first mask image obtained by performing the OPC method according to some embodiments described with reference to FIG. 11A.

There may be a difference between the first line L1 and the second line L2 with respect to a peak region R1 of the optical image for the auxiliary pattern AP. In detail, in FIG. 16A, a value of a first peak PK1 of the first line L1 is shown to be less than a value of a second peak PK2 of the second line L2, but embodiments are not limited thereto. Depending on a size, shape, and arrangement of the auxiliary pattern AP, the second peak PK2 may be less than the first peak PK1. The first peak PK1 may indicate a peak value of an optical image for a corrected first mask image of the auxiliary pattern AP according to a comparative example. Here, the corrected first mask image of the auxiliary pattern AP may indicate a mask image corrected by performing an edge filter process and a coupling edge filter process on the first mask image of the auxiliary pattern AP. The second peak PK2 may indicate a peak value of an optical image for a corrected first mask image of the auxiliary pattern AP according to some embodiments. Here, the corrected first mask image of the auxiliary pattern AP may indicate a mask image corrected by performing an edge filter process on the first mask image of the auxiliary pattern AP and omitting the coupling edge filter process.

When comparing the profiles of the first line L1 and the second line L2, consistency of the OPC method according to some embodiments may be lowered due to a difference between the first peak PK1 and the second peak PK2. In summary, when performing the OPC method according to some embodiments, the OPC processing time may be remarkably reduced compared to performing the OPC method according to the comparative example. However, as described above, when performing the OPC method according to some embodiments, the consistency of the optical image may be lower than performing the OPC method according to the comparative example.

While adopting embodiments that remarkably reduce the OPC processing time by omitting the finding coupling edge pairs for the auxiliary pattern AP, the following operations may be further performed to solve the above problem.

After the performing of the second correction for correcting the first mask image by performing the coupling edge filter process on the main pattern MP in S33, generating a second mask image for an auxiliary pattern AP through a first additional correction and a second additional correction on a first mask image of the auxiliary pattern AP in S331 and generating a final mask image by subtracting or adding the second mask image from or to the corrected first mask image of the main pattern MP and the auxiliary pattern AP may be performed in S332. Thereafter, the above-described simulation performance and optimization in S34 may be performed. The order of the above-described process operations is not limited as above and may be variously changed by a person skilled in the art.

First, the operations in S331 and S332 will be described with reference to FIGS. 14, 15, 16B, and 16C. FIG. 16B is a graph illustrating an optical image of the second line L2 described with reference to FIG. 16A. FIG. 16C is a graph illustrating a first mask image of the auxiliary pattern AP and a second mask image obtained by performing a first additional correction and a second additional correction on the first mask image of the auxiliary pattern AP. In detail, in FIG. 16C, a third line L3 (which is shown as a dashed line) may represent the first mask image of the auxiliary pattern AP, and a fourth line L4 (which is shown as a solid line) may represent the second mask image obtained by performing the first additional correction and the second additional correction on the first mask image of the auxiliary pattern AP.

First, performing the first additional correction may include blurring the first mask image of the auxiliary pattern AP. Blurring the first mask image of the auxiliary pattern AP may include applying a Gaussian convolution (or Gaussian filter) to the third line L3 to remove high frequency components of the third line L3. Accordingly, a sharp peak of the third line L3 may be smoothed out, such as a peak of the fourth line L4.

Thereafter, performing the second additional correction may include calculating a difference between the first peak PK1 and the second peak PK2 described with reference to FIG. 16A and applying an appropriate coefficient value to the third line L3 that has undergone the first additional correction.

For example, a difference between the first peak PK1 and the second peak PK2 (i.e., a value of the first peak PK1 minus a value of the second peak PK2) described with reference to FIG. 16A may have a negative value. To compensate for the difference, the coefficient value may have a negative value. When the difference between the first peak PK1 and the second peak PK2 described with reference to FIG. 16A has a negative value, the second additional correction may include applying a negative coefficient value to the third line L3 that has undergone the first additional correction. Accordingly, in the fourth line L4, the peak of the auxiliary pattern AP may have a convex shape facing downward.

In another example, unlike what was described with reference to FIG. 16A, a difference between the first peak PK1 and the second peak PK2 (i.e., a value of the first peak PK1 minus a value of the second peak PK2) may have a positive value. To compensate for the difference, the coefficient value may have a positive value. Referring to FIG. 16D, when the difference between the first peak PK1 and the second peak PK2 described with reference to FIG. 16A has a positive value, unlike that described with reference to FIG. 16C, the second additional correction may include applying a positive coefficient value to the third line L3 that has undergone the first additional correction. Accordingly, in the fourth line L4, a peak of the auxiliary pattern AP may have a convex shape facing upward. In FIG. 16D, the fourth line L4 may represent a second mask image obtained by performing the first additional correction and the second additional correction on the first mask image of the auxiliary pattern AP.

Referring to FIG. 17, a fifth line L5 of FIG. 17 (shown as a dashed line) represents the second line L2 minus the fourth line L4 of FIG. 16D. That is, the fifth line L5 represents the optical image of the first mask image after the first correction and the second correction minus the second mask image. Unlike the difference between the first line L1 and the second line L2 in the first peak region R1 described with reference to FIG. 16A, the first line L1 (shown as a solid line) and the fifth line L5 in the first peak region R1 of FIG. 17 may be substantially the same/similar.

When the difference between the first peak PK1 and the second peak PK2 (i.e., a value of the first peak PK1 minus a value of the second peak PK2) described with reference to FIG. 16A has a positive value, the fifth line L5 may represent the second line L2 plus the fourth line L4 of FIG. 16D.

According to embodiments, the OPC method may subtract or add the second mask image of the auxiliary pattern AP generated through the first additional correction and the second additional correction from or to the first mask image that has undergone the first correction and the second correction. Accordingly, the OPC method of embodiments without applying the coupling edge filter process to the auxiliary pattern AP may have OPC consistency similar to that of the comparative example. As a result, reliability of the OPC method may be maintained while reducing the time required for the OPC method. Accordingly, productivity of the semiconductor device manufacturing method may be improved.

The appropriate Gaussian convolution value for performing the first additional correction and the appropriate coefficient value for performing the second additional correction may be variously changed depending on the width of the auxiliary pattern AP. The appropriate Gaussian convolution value and the appropriate coefficient value may be obtained by calculating the difference (max error ratio, MER) between the mask image according to the OPC method and the mask image according to the OPC method of the comparative example, as changing the width of the auxiliary pattern AP. That is, as changing the width of the auxiliary pattern AP, the MER described above may be obtained for each width of the auxiliary pattern AP, and accordingly, the Gaussian convolution value and the coefficient value may be optimized. The optimized Gaussian convolution values and the optimized coefficient value values may be stored in advance in the OPC program. The user may set an appropriate Gaussian convolution value and an appropriate coefficient value among the optimized Gaussian convolution values and the optimized coefficient value values depending on the width of the auxiliary pattern AP arranged in the layout LO.

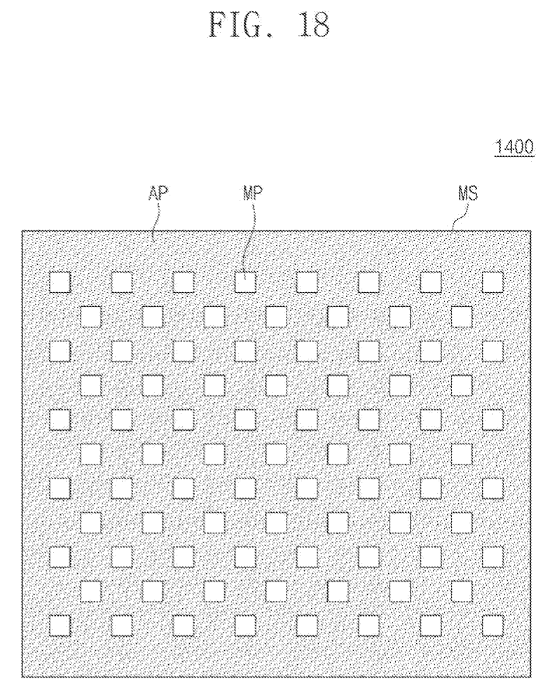

FIG. 18 is a plan view illustrating a photomask according to some embodiments.

Referring to FIG. 2 and FIG. 18, a photomask 1400 may be formed based on a layout in which a final mask image is reflected in S40. The photomask 1400 may include a mask MS, main patterns MP in the mask MS, and auxiliary patterns AP surrounding the main patterns MP in the mask MS.

The photomask 1400 may include a transparent region and an opaque region. The opaque region may block light without transmitting the light. On the other hand, the transparent region may transmit light emitted from a light source 1200 of FIG. 3. The light passing through the photomask 1400 may be irradiated onto the substrate SUB of FIG. 3. For example, in the case of a photolithography process using a negative photoresist, the main patterns MP may be transparent regions of the photomask 1400.

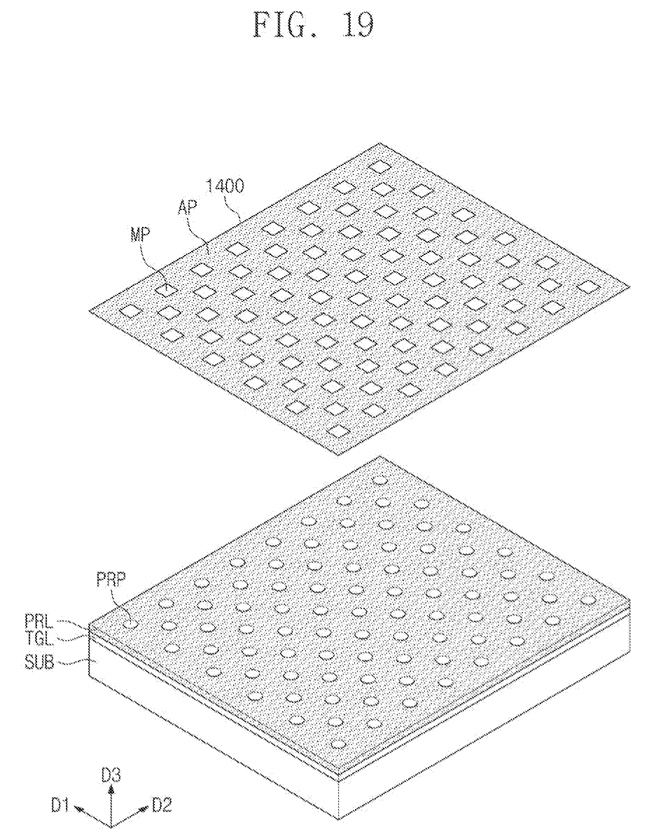

FIG. 19 is a conceptual diagram illustrating the formation of photoresist patterns on a substrate using the photomask of FIG. 18.

Referring to FIG. 19, the light source 1200 of FIG. 3 may emit light to the photomask 1400. The emitted light may pass through the transparent regions of the auxiliary patterns AP and the main patterns MP, and be irradiated onto a photoresist layer PRL on a substrate SUB (exposure process). The region of the photoresist layer PRL irradiated with the light may become a photoresist pattern PRP.

By performing a subsequent development process, the photoresist patterns PRP may remain and the other photoresist layer PRL may be removed. The photoresist patterns PRP may be used as an etching mask to pattern an etching target layer TGL on a substrate SUB. As a result, the desired target patterns may be implemented on the substrate SUB. As a result, by implementing the target patterns for each layer described above, a semiconductor device may be manufactured in S50 (see FIG. 2).

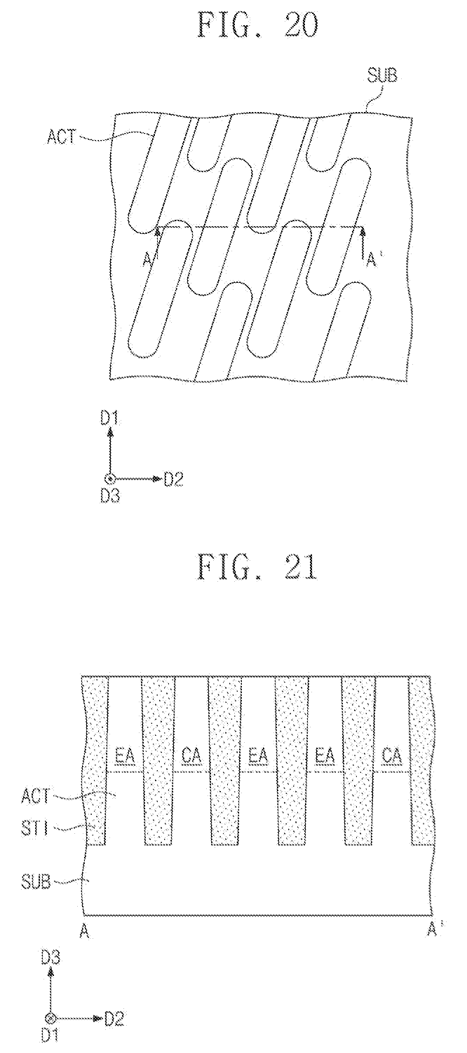

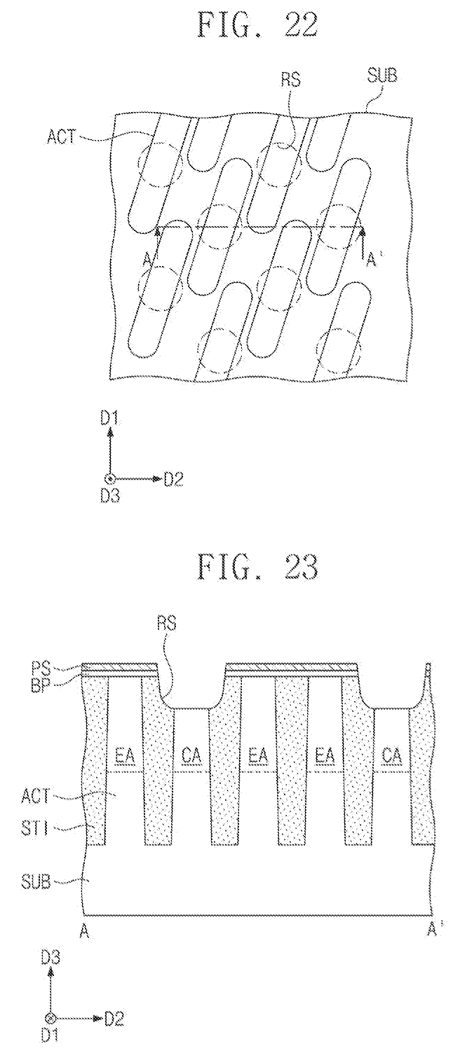

FIGS. 20 to 27 are drawings illustrating a method of manufacturing a semiconductor device according to some embodiments. In detail, FIGS. 20, 22, 24, and 26 are plan views illustrating a method of manufacturing a semiconductor device according to some embodiments, respectively. FIGS. 21, 23, 25, and 27 are cross-sectional views corresponding to lines A-A’ of FIGS. 20, 22, 24, and 26, respectively.

Referring to FIGS. 20 and 21, active patterns ACT may be formed by patterning an upper portion of a substrate SUB. Each of the active patterns ACT may extend in a direction parallel to the upper surface of the substrate SUB. The active patterns ACT may be disposed to be spaced apart from each other in the first direction D1 and the second direction D2.

The active patterns ACT may be formed using a photolithography process. A photomask used in the photolithography process for implementing the active patterns ACT may be formed using the OPC method according to some embodiments described above.

According to one embodiment, a patterning process for forming the active patterns ACT may include an EUV lithography process. The EUV lithography process may include an exposure and development process using EUV irradiated onto a photoresist layer. For example, the photoresist layer may be an organic photoresist containing an organic polymer such as polyhydroxystyrene. The organic photoresist may further include a photosensitive compound that reacts to EUV. The organic photoresist may further include a material having a high EUV absorption rate, for example, an organometallic material, an iodine-containing material, or a fluorine-containing material. As another example, the photoresist layer may be an inorganic photoresist containing an inorganic material such as tin oxide.

The photoresist layer may be formed to have a relatively thin thickness. The photoresist patterns may be formed by developing the photoresist layer exposed to EUV. When viewed in a plan view, the photoresist patterns may have a line shape extending in one direction, an island shape, a zigzag shape, a honeycomb shape, or a circle shape, but are not limited thereto.

The photoresist patterns may be patterned with one or more mask layers stacked therebelow as an etching mask to form mask patterns. A target layer may be patterned with the mask patterns as an etching mask to form desired patterns on the wafer.

For example, a minimum pitch between active patterns ACT implemented by the EUV lithography process of the present embodiment may be 45 nm or less. That is, precise and fine active patterns ACT may be implemented with one photo mask by performing the EUV lithography process.

Trenches may be formed between the active patterns ACT, and a device isolation layer STI filling the inside of the trench may be formed.

Referring to FIGS. 22 and 23, a word line may be formed across the active patterns ACT. Forming the word line may include sequentially forming a gate dielectric pattern, a gate electrode, and a gate capping pattern.

A buffer pattern BP and a polysilicon pattern PS may be sequentially formed on the substrate SUB. The buffer pattern BP and the polysilicon pattern PS may be formed to cover the active patterns ACT and the device isolation layer STI.

A recess region RS may be formed on a central portion CA of each of the active patterns ACT. During the process of forming the recess region RS, the buffer pattern BP and the polysilicon pattern PS may be partially removed. The recess region RS may be implemented using a photolithography process. The photomask used in the photolithography process for implementing the recess region RS may be formed through the OPC method according to embodiments described above.

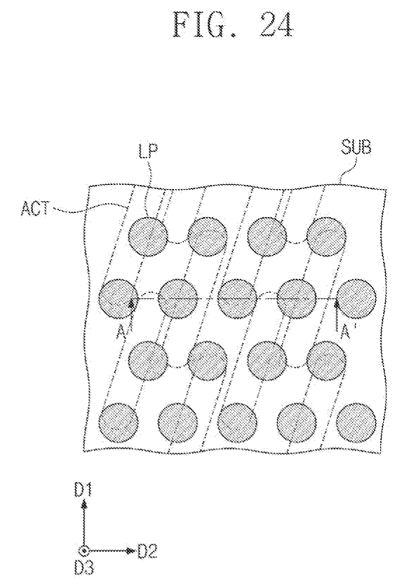

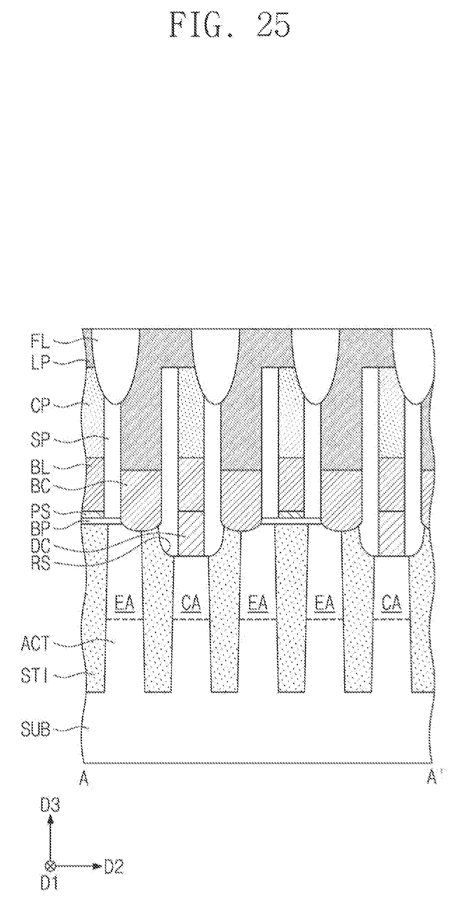

Thereafter, referring to FIG. 24 and FIG. 25, bit line structures extending in the first direction D1 and spaced apart from each other in the second direction D2 may be formed on the central portion CA of the active pattern ACT. Each of the bit line structures may include a bit line contact DC, a bit line BL, and a bit line capping pattern CP sequentially provided on the central portion CA of the active pattern ACT. Bit line spacers SP covering side surfaces of the bit line structures may be formed.

Storage node contacts BC may be formed between the bit line structures. Landing pads LP may be formed on the storage node contacts BC. Upper portions of the landing pads LP may be shifted in the second direction D2 relative to lower portions thereof, respectively. The upper portions of the landing pads LP may be implemented using a photolithography process. The photomask used in the photolithography process for implementing the upper portions of the landing pads LP may be formed using the OPC method according to embodiments described above. A filling layer FL surrounding the upper portions of the landing pads LP may be formed.

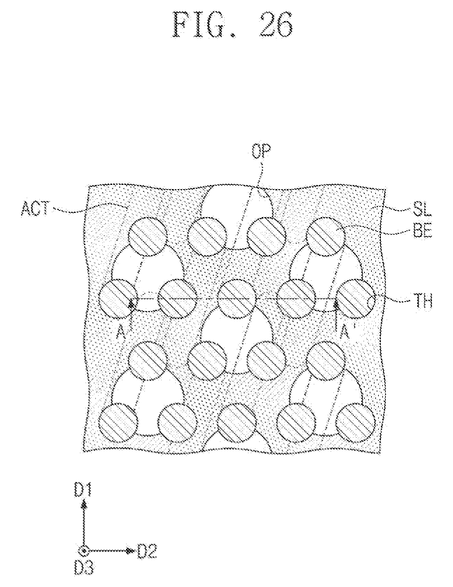

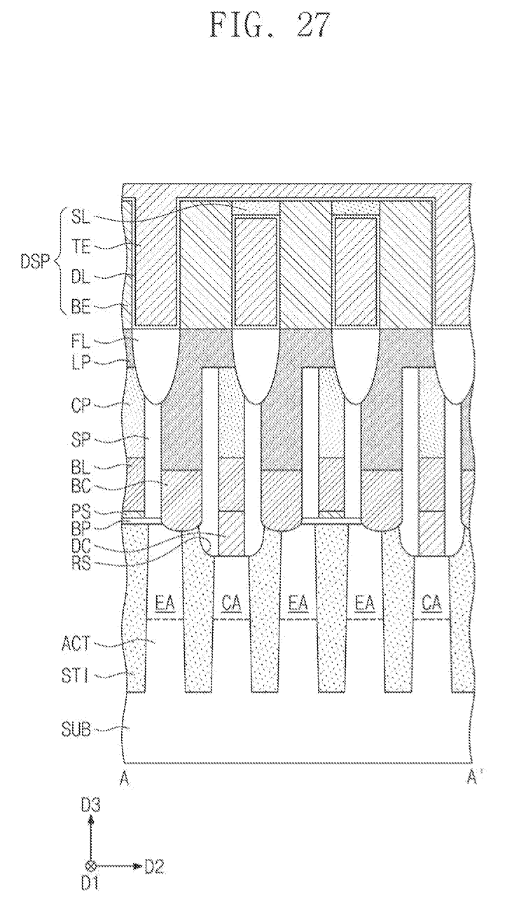

Referring to FIGS. 26 and 27, a data storage pattern DSP may be formed on the landing pads LP. The data storage pattern DSP may include a lower electrode BE on the upper portions of the landing pads LP, an upper electrode TE on the lower electrode BE, a dielectric layer DL between the lower electrode BE and the upper electrode TE, and a support layer SL connected to an upper portion each of the lower electrodes BE.

For example, forming the lower electrodes BE may include forming a mold layer and the support layer SL on the filling layer FL, performing a removal process on a portion of each of the mold layer and the support layer SL to form penetration holes TH, and forming the lower electrodes BE in the penetration holes TH.

When forming the penetration holes TH, a photolithography process may be utilized. A photomask used in the photolithography process for implementing the penetration holes TH may be formed through the OPC method according to embodiments described above.

For example, forming the dielectric layer DL and the upper electrode TE may include forming openings OP inside the support layer SL, removing the mold layer using the openings OP as a path, and forming the dielectric layer DL and the upper electrode TE in an region where the mold layer is removed.

When forming the openings OP, a photolithography process may be utilized. The photomask used in the photolithography process for implementing the openings OP may be formed through the OPC method according to embodiments.

According to embodiments, the coupling edge filter process may be applied to the layout, while the coupling edge filter process for the auxiliary pattern is omitted. Accordingly, only the coupling edge filter process for the main pattern may be performed. As a result, the time required for the OPC method may be reduced. Accordingly, the productivity of the semiconductor device manufacturing method may be improved.

In addition, with the above-described OPC method, subtracting or adding the second mask image performing the first additional correction and the second additional correction from or to the mask image performing the edge filter process and the coupling edge filter process for the layout may be performed, thereby improving the consistency of the OPC method. As a result, the reliability of the OPC method may be maintained while reducing the time required for the OPC method. Accordingly, the productivity of the semiconductor device manufacturing method may be improved.

While aspects of embodiments are described above, a person skilled in the art may understand that many modifications and variations are made without departing from the spirit and scope of the inventive concept defined in the following claims.

What is claimed is:

1. A method of manufacturing a semiconductor device, method comprising:
performing optical proximity correction on a layout to generate a corrected layout; and
forming a photoresist pattern on a substrate using a photomask formed using the corrected layout,
wherein the performing of the optical proximity correction comprises:
generating a first mask image for a mask pattern, the first mask image comprising a main pattern and an auxiliary pattern in the layout; and
performing a coupling filter process on the mask pattern in the layout to correct the first mask image,
wherein the performing of the coupling filter process comprises extracting coupling edge pairs of the mask pattern and applying a coupling edge filter to at least one of the extracted coupling edge pairs, and
wherein the performing of the coupling filter process is omitted for the auxiliary pattern.

2. The method of claim 1, wherein the generating of the first mask image for the mask pattern comprises generating a mask image by a thin mask approximation of the mask pattern.

3. The method of claim 1, wherein the performing of the coupling filter process comprises extracting coupling edge pairs of the main pattern and applying the coupling edge filter to the extracted coupling edge pairs of the main pattern, and omitting the extracting of coupling edge pairs of the auxiliary pattern.

4. The method of claim 3, wherein the performing of the coupling filter process comprises omitting the applying of the coupling edge filter to the coupling edge pairs of the auxiliary pattern.

5. The method of claim 1, further comprising generating a second mask image for the auxiliary pattern through a first additional correction and a second additional correction for the first mask image of the auxiliary pattern.

6. The method of claim 5, further generating a final mask image based on a difference between the second mask image and the corrected first mask image of the main pattern, and a difference between the second mask image the auxiliary pattern obtained by the performing of the coupling filter process.

7. The method of claim 5, wherein the first additional correction comprises blurring the first mask image of the auxiliary pattern, and
wherein the second additional correction comprises applying a coefficient value to the blurred first mask image.

8. The method of claim 1, further comprising performing an edge filter process on the mask pattern in the layout to correct the first mask image,
wherein the performing of the edge filter process comprises extracting edges of the main pattern, and applying an edge filter to the extracted edges to correct the first mask image.

9. The method of claim 1, wherein the auxiliary pattern comprises a plurality of auxiliary patterns adjacent to the main pattern, and
wherein the plurality of auxiliary patterns comprises sub-resolution assist features (SRAF).

10. The method of claim 9, wherein the plurality of auxiliary patterns comprises at least one pattern having an amorphous shape.

11. A method of manufacturing a semiconductor device, the method comprising:
performing optical proximity correction on a layout to generate a corrected layout; and
forming a photoresist pattern on a substrate using a photomask formed using the corrected layout,
wherein the optical proximity correction comprises:
generating a first mask image for a main pattern and an auxiliary pattern in the layout;
extracting edges of the main pattern;
performing a first correction of applying an edge filter to the edges of the main pattern to correct the first mask image; and
performing a second correction of extracting coupling edge pairs from the edges of the main pattern and applying a coupling edge filter to at least one of the extracted coupling edge pairs to correct the first mask image, and
wherein the extracting of coupling edge pairs from edges of the auxiliary pattern is omitted.

12. The method of claim 11, wherein the applying of the coupling edge filter to the coupling edge pairs from the edges of the auxiliary pattern is omitted.

13. The method of claim 11, further comprising generating a second mask image of the auxiliary pattern through a first additional correction and a second additional correction for the first mask image of the auxiliary pattern.

14. The method of claim 13, further comprising generating a final mask image based on a difference between the second mask image and the corrected first mask image of the main pattern, and a difference between the second mask image of the auxiliary pattern obtained by performing the first additional correction and the second additional correction.

15. The method of claim 13, wherein the performing of the first additional correction comprises blurring the first mask image of the auxiliary pattern, and
wherein the performing of the second additional correction comprises applying a coefficient value to the blurred first mask image.

16. The method of claim 11, wherein the auxiliary pattern comprises a plurality of auxiliary patterns adjacent to the main pattern, and
wherein the plurality of auxiliary patterns comprises sub-resolution assist features (SRAF).

17. A method of manufacturing a semiconductor device, the method comprising:
generating a first mask image for a main pattern and an auxiliary pattern in a layout;
extracting edges of the main pattern;
performing a first correction of correcting the first mask image by applying an edge filter to the edges of the main pattern;
performing a second correction of correcting the first mask image by extracting coupling edge pairs from the edges of the main pattern and applying a coupling edge filter to the extracted coupling edge pairs to generate a final mask image;
obtaining a photomask with a corrected layout comprising the main pattern and the auxiliary pattern having the final mask image;
forming an etching target layer and a photoresist layer on a substrate;
exposing and developing the photoresist layer with the photomask to form photoresist patterns; and
patterning the etching target layer using the photoresist patterns,
wherein the extracting of coupling edge pairs from edges of the auxiliary pattern is omitted.

18. The method of claim 17, further comprising generating a second mask image of the auxiliary pattern through a first additional correction and a second additional correction for the first mask image of the auxiliary pattern,
wherein the performing of the first additional correction comprises blurring the first mask image of the auxiliary pattern, and
wherein the performing of the second additional correction comprises applying a coefficient value to the blurred first mask image.

19. The method of claim 18, wherein the generating of the final mask image further comprises obtaining a difference between the second mask image and the corrected first mask image of the main pattern, and obtaining a difference between the second mask image and the auxiliary pattern obtained by performing the first correction and the second correction.

20. The method of claim 17, wherein the auxiliary pattern comprises a plurality of auxiliary patterns adjacent to the main pattern,
wherein the plurality of auxiliary patterns comprises sub-resolution assist features (SRAF), and
wherein the plurality of auxiliary patterns comprises at least one pattern having an amorphous shape.
